(19) United States
(12) Patent Application Publication
(10) Pub. No.: US 2006/0092316 A1
(43) Pub. Date: May 4, 2006

(54) Boost signal interface method and apparatus

(76) Inventor: William G. Gazeley, Corvallis, OR (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/981,011

(22) Filed: Nov. 3, 2004

(51) Int. Cl. H04N 5/225; H01L 27/00; H04N 5/217; H04N 3/14; H04N 5/335

(52) U.S. Cl. 348/372; 250/208.1; 348/241; 348/302

(57) ABSTRACT

An apparatus and method for providing a boost signal to a pixel array that includes a plurality of rows are described. The apparatus includes a first input that receives a boost signal. The apparatus also includes a second input that receives at least one control signal and a third input that receives a reset enable signal. The apparatus also includes a plurality of outputs. Each output is coupled to a corresponding row of the pixel array. The apparatus selectively provides the boost signal at one of the outputs based on the control signal and the reset enable signal.

### BACKGROUND OF THE INVENTION

Recently, cellular telephones or handsets equipped with a digital camera (also known as “camera phones”) have become available and are a popular item among consumers. By adding a camera functionality to the ubiquitous cellular telephone, consumers are more apt to take digital pictures to share with friends, etc. Furthermore, new camera-enabled mobile applications such as multimedia messaging, visual caller identification, and mobile photo albums have become popular with consumers. These popular applications coupled with the growing worldwide demand for camera-enabled handsets have made mobile imaging an essential feature for handsets in many markets.

Consequently, mobile handsets manufactures manufacturers are faced with the need to incorporate the functions of a digital camera into the cellular telephone. Agilent Technologies, Inc., the assignee of the current application, is a market leader in CMOS imaging solutions and a leading supplier of semiconductor solutions for today's highly integrated, feature-rich mobile handsets and offers embedded camera modules for mobile handsets manufactures.

An important component in the camera module is the image sensor integrated circuit that includes a pixel array with a plurality of pixels that are arranged in rows and columns. Each pixel receives light and converts the received light into a corresponding analog signal that represents the received light. Specifically, each pixel in a row is reset to a predetermined signal (e.g., a predetermined reset voltage). The pixels in the row are then integrated for a predetermined time period. During integration, the pixels receive light and decreases the reset voltage to a signal that represents the amount of light received at the pixel. For example, pixels that have a value close to the reset voltage appear dark in the picture, whereas pixels that have a value close to zero, appear as bright spots in the picture.

One challenge faced by designers is the reduction in the power supply voltage that is caused by consumer demand for longer battery life and longer operating time of the electronic device between charges. Unfortunately, as the power supply voltage is decreased, the dynamic range of the system also decreases.

One approach to increase dynamic range while reducing the power supply voltage is to employ a boost generator that generates a reset voltage (also referred to as a “boost signal”) that is higher than the power supply voltage and provides this boost signal to the pixel array.

However, the design of the boost generator and how to interface the boost generator to the pixel array pose significant challenges and introduces new issues and design concerns. First, the design should minimize the amount of parasitic capacitance as seen by the boost generator. A large parasitic capacitance complicates the design of the boost generator and also increases the size of the boost generator, thereby increasing the space or area occupied by the boost generator. Second, the design should be space efficient and conserve the amount of area utilized since most portable applications are compact and space is limited.

Based on the foregoing, there remains a need for a method and apparatus that interfaces a boost generation circuit with a pixel array that overcomes the disadvantages set forth previously.

### SUMMARY OF THE INVENTION

According to one embodiment of the present invention, an apparatus and method for providing a boost signal to a pixel array that includes a plurality of rows are described. The apparatus includes a first input that receives a boost signal. The apparatus also includes a second input that receives at least one control signal and a third input that receives a reset enable signal. The apparatus also includes a plurality of outputs. Each output is coupled to a corresponding row of the pixel array. The apparatus selectively provides the boost signal at one of the outputs based on the control signal and the reset enable signal.

### BRIEF DESCRIPTION OF THE DRAWINGS

The present invention is illustrated by way of example, and not by way of limitation, in the figures of the accompanying drawings and in which like reference numerals refer to similar elements.

FIG. 1 illustrates a block diagram of an image sensor that includes a boost signal interface mechanism according to one embodiment of the invention.

FIG. 2 illustrates in greater detail the boost signal interface mechanism of FIG. 1 according to a first embodiment of the invention.

FIG. 3 illustrates in greater detail the boost signal interface mechanism of FIG. 1 according to a second embodiment of the invention.

FIG. 4 is a circuit diagram of an exemplary implementation of the boost signal interface mechanism of FIG. 3 according to one embodiment of the invention.

FIG. 5 is a flowchart illustrating a method performed by the boost signal interface mechanism of FIG. 3 according to one embodiment of the invention.

FIG. 6 is a block diagram illustrating a camera module that includes the boost signal interface circuit according to one embodiment of the invention.

### DETAILED DESCRIPTION

A method and apparatus for providing a boost signal to a pixel array are described. In the following description, for the purposes of explanation, numerous specific details are set forth in order to provide a thorough understanding of the present invention. It will be apparent, however, to one skilled in the art that the present invention may be practiced without these specific details. In other instances, well-known structures and devices are shown in block diagram form in order to avoid unnecessarily obscuring the present invention.

Image Sensor 100

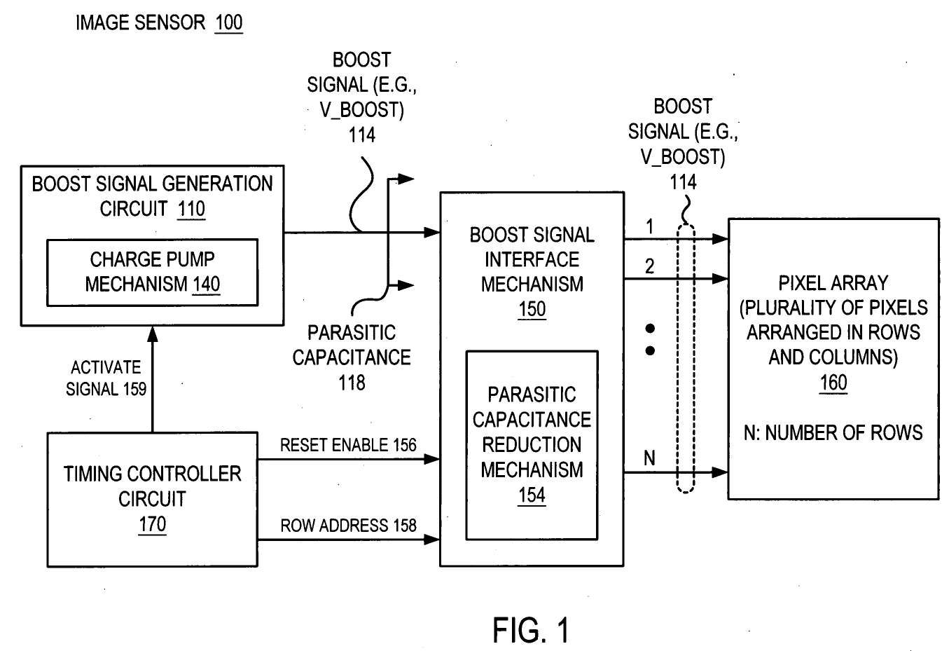

FIG. 1 illustrates a block diagram of an image sensor 100 that includes a boost signal interface mechanism 150 according to one embodiment of the invention. The image sensor 100 includes a boost signal generation circuit 110, a pixel array 160, a mechanism for interfacing the boost signal generation circuit 110 with the pixel array (hereinafter referred to as a boost signal interface mechanism 150), and a timing controller circuit 170.

Boost Signal Generation Circuit 110

The boost signal generation circuit 110 generates a boost signal (e.g., a voltage signal that is referred to herein as V_boost or V_reset) that is above a power supply signal (e.g., an analog power supply voltage signal) in order to increase dynamic range. In one embodiment, the boost signal generation circuit 110 is implemented with a charge pump mechanism 140 that employs a boost capacitor to distribute charge from the boost capacitor to a load capacitor (e.g., the capacitors in each pixels of a selected row in the pixel array). This redistribution of charge causes a voltage change at the load capacitor that in turn resets the voltage at a particular node in the pixel, for example, in preparation for integration (e.g., collection of light).

The timing controller circuit 170 generates a row address 158, a reset enable signal 156, and an activate signal 159 that when asserted activates the boost signal generation circuit 110. The timing controller circuit 170 also generates row timing signals (e.g., the reset enable signal 156 that initiates integration and a row select signal that initiates readout of pixel values), column address, and column timing signals that are not shown. The construction and operation of timing controller circuit 170 is known by those of ordinary skill in the art and will not be described in greater detail herein. Preferably, the timing controller circuit 170 generates a row address 158 that is a binary group of bits that can be divided into at least two groups: a first group of upper bits and a second group of lower bits. The row address 158 may be decoded to generate switch control signals as described in greater detail hereinafter.

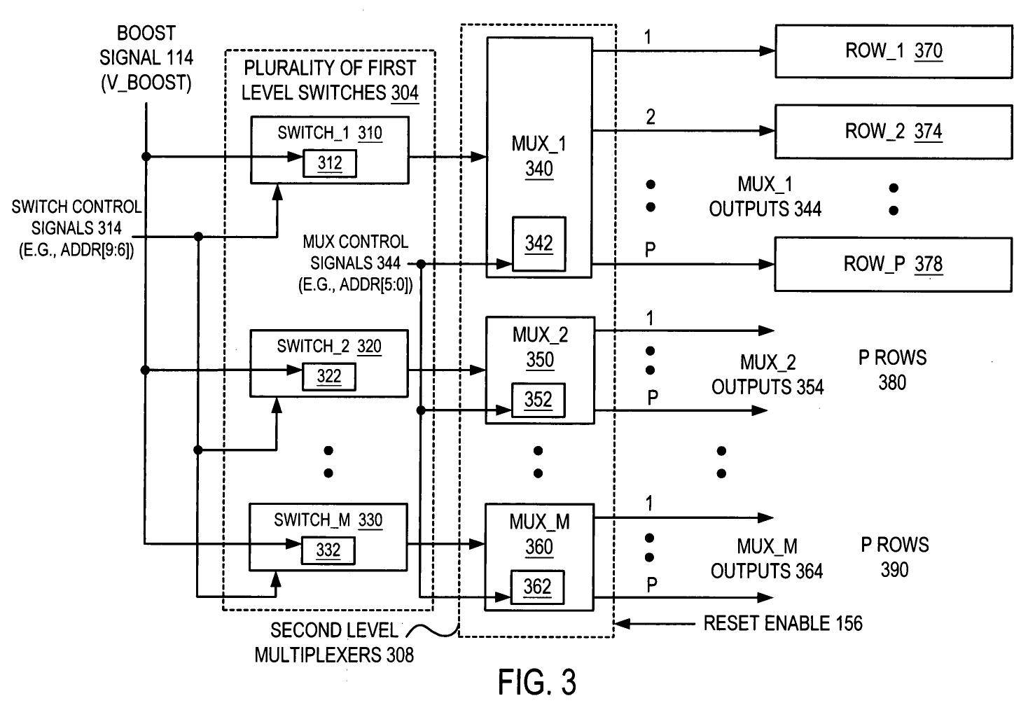

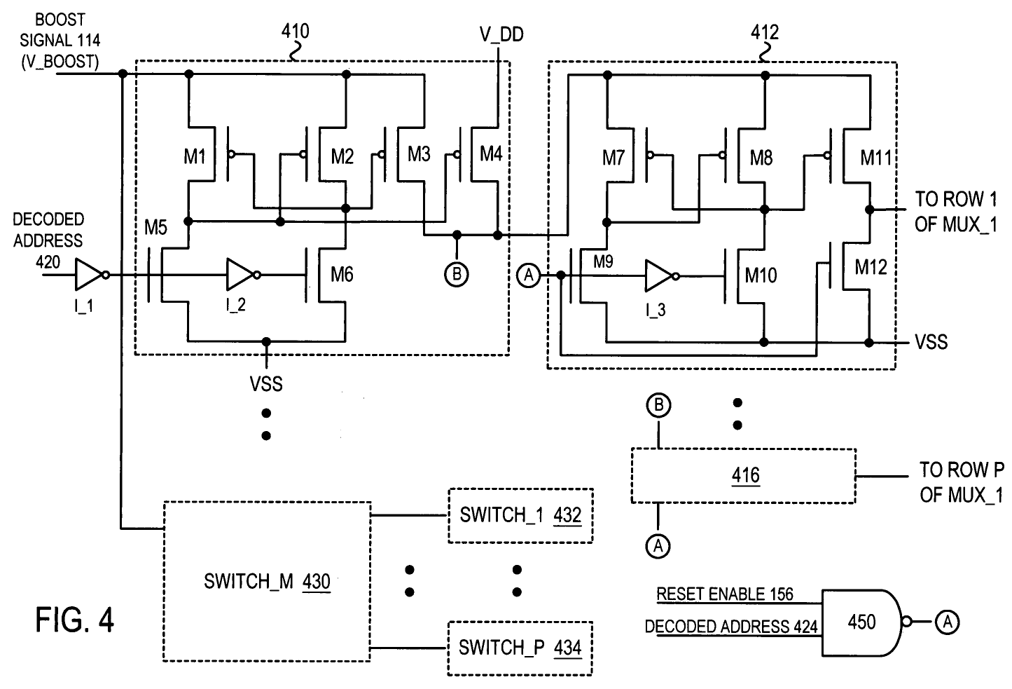

The boost signal interface mechanism 150 is coupled to the boost generation circuit 110 and the pixel array 160 and provides an interface there between. For example, boost signal interface mechanism 150 (also referred to herein as “boost signal interface circuit”) includes an input that receives the boost signal 114 from the boost signal generation circuit 110, a second input that receives a reset enable signal 156 (also referred to herein as “enable reset signal”), and a third input for receiving the row address signals 158 that can subsequently be decoded into switch control signals. The boost signal interface mechanism 150 selectively provides the boost signal 114 to one of the rows of the pixel array 160 based on the reset enable signal 156 and the control signals 158. The boost signal 114, the reset enable signal 156 and the control signals and the operation of the boost signal interface mechanism 150 are described in greater detail hereinafter with reference to FIGS. 3 and 4.

One aspect of the boost signal interface mechanism 150 according to one embodiment of the invention is to provide an interface to the pixel array 160 for the boost signal 114 that achieves one or more of the following: 1) reduces or minimizes the amount of parasitic capacitance seen by the boost signal generation circuit 110; 2) reduces or minimizes the amount of space occupied by the interface mechanism 150; 3) integrates well into existing pixel array architectures, and 4) avoids introducing row-to-row offsets.

The boost signal interface mechanism 150 includes a parasitic capacitance reduction mechanism 120. The effective parasitic capacitance reduction mechanism 120 reduces the effective parasitic capacitance (C_L) 118 (e.g., the parasitic capacitance or capacitive load seen by the boost generation circuit 110). By minimizing or reducing the effective parasitic capacitance of the interface mechanism 150, one embodiment of the invention advantageously conserves space or area by reducing the size of the boost capacitor. Consequently, the size of the boost capacitor of the boost signal generator 110 can be reduced to a size that is less than if the boost signal generation circuit 110 were exposed to a larger parasitic capacitance were generated by the interface.

The pixel array 160 includes a plurality of pixels that can be arranged in rows and columns. In an example provided hereinafter with reference to FIG. 3, the number of rows in the pixel array 160 is denoted by “N.” For example, pixel array 160 can be a mega-pixel array that has over a million pixels. In this case, the number of rows (N) typically is equal to or greater than 1024, and the number of columns typically also is equal to or greater than 1024. It is noted that the boost signal interface mechanism 150 can be applied to pixels arrays having any size (e.g., an A x B pixel array with A rows and B columns).

It is noted that the boost signal interface mechanism 150 may be implemented in part or in whole in the boost signal generation circuit 110, in part or in whole in the pixel array 160, or separate from the boost signal generation circuit 110 and the pixel array 160.

### FIRST EMBODIMENT OF BOOST SIGNAL INTERFACE MECHANISM 150

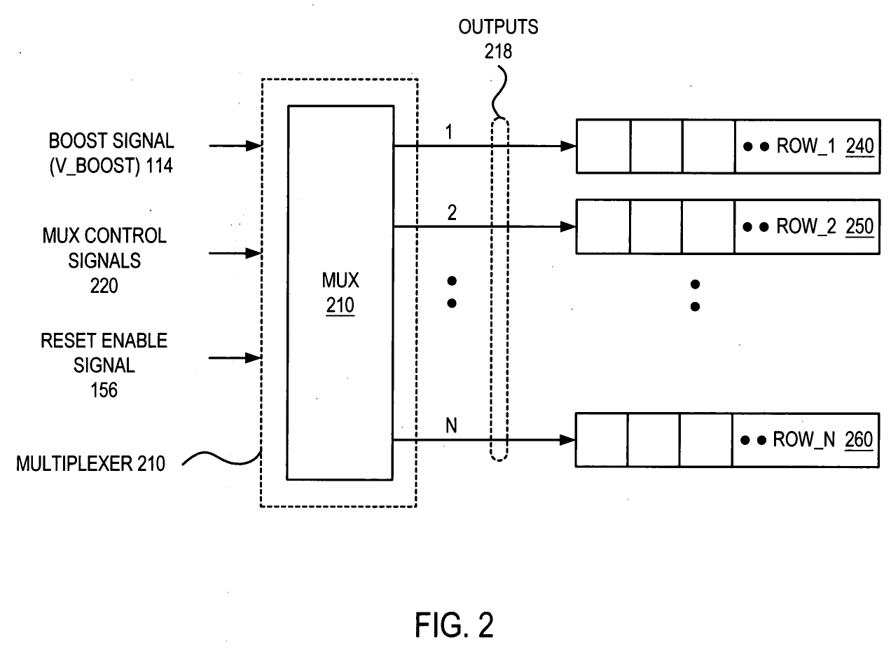

FIG. 2 illustrates in greater detail the boost signal interface mechanism 150 of FIG. 1 according to a first embodiment of the invention. The boost signal interface mechanism 150 includes a multiplexer 210 that includes a plurality of inputs and a plurality of outputs 218. The inputs includes a first input that receives a boost signal (V BOOST) 114, a second input that receives MUX control signals 220 (e.g., row address control signals ADDR[9:0] or signals derived there from), and a third input that receives the reset enable signal 156. Based on the control signal 220 and the reset enable signal 156, the multiplexer 210 selectively routes the boost signal to one of the outputs 218. It is noted that the MUX control signals 220 (e.g., row address control signals ADDR[9:0]) and reset enable signal 156 may be generated by a timing controller circuit 170.

One method for designing the multiplexer 210 is “flat” (i.e., V_boost 114 drives the input of all the switches, where there is one switch per row). As can be appreciated and as described in greater detail hereinafter, a “flat” design exposes the boost signal generation circuit 110 to a higher parasitic capacitance, especially with a mega-pixel design with more than a thousand rows. The multiplexer 210 selectively provides the boost signal 114 at one of the outputs 218, which is coupled to a corresponding row of a pixel array. For example, a first output is coupled to a first row (ROW_1 240); a second output is coupled to a second row (ROW_2 250), and an Nth output is coupled to the Nth row (ROW_N 260).

### SECOND EMBODIMENT OF BOOST SIGNAL INTERFACE MECHANISM 150

FIG. 3 illustrates in greater detail the boost signal interface mechanism 150 of FIG. 1 according to a second embodiment of the invention. In this embodiment, a method and apparatus are disclosed that employ a hierarchical switching structure to provide the boost signal 114 (e.g., a reset signal that is higher than the power supply voltage signal) to the pixel array 160.

As discussed previously, reducing the boost capacitor is desirable because the boost capacitor is typically placed in a corner outside the pixel array circuitry, where space is limited. Because the pixel array contains many elements, extra design effort is expended to make each individual element in the pixel array small. For example, the pixels, the row control circuits and row read-out circuits, and column control circuits and column read-out circuits are designed in a manner to conserve space. It is noted that the interface mechanism according to the invention (e.g., the hierarchical switching structure design) is suitable for integration into these types of space-conserving designs. For example, the interface mechanism according to the invention may be integrated into row control circuits and row read-out circuits.

According to this embodiment, the boost signal interface mechanism 150 includes a plurality 304 of first level switches (e.g., switch_1 310, switch_2 320, . . . switch_M 330). Each first level switch (e.g., 310, 320, 330) includes a first input for receiving the boost signal 114 (e.g., V_boost signal), a second input for receiving signals 314 (e.g., selected bits of a row address), and an output for providing the boost signal based on the switch control signals 314. Each first level switch includes decode logic (e.g., decode logic 312, 322 and 332) that receives signals 314 and based thereon generates a control signal (e.g., switch control signal) for controlling the respective first level switch. For example, the control signal may be utilized to turn ON or OFF the respective switch.

The decode logic 312, 322, and 332 may be implemented with well-known logic circuits and logic gates. For example, decode logic can be an AND gate with inputs that receive selected bits from the row address and a single output that generates a switch control signal that selectively turns ON or OFF the respective first level switch. For example, for the first level switch denoted by binary “0000”, the decode logic can be implemented with an AND gate with inverted inputs for all received address bits. Similarly, for the first level switch denoted by binary “0001”, the decode logic can be implemented with an AND gate with inverted inputs for the upper three bits and a non-inverted input for the lowest bit. Similarly, for the first level switch denoted by binary “1111”, the decode logic can be implemented with an AND gate with non-inverted inputs for all four input bits.

In one embodiment, the control signals for each first level switch are generated based on selected bits from the row address 158. For example, in a mega-pixel array with 1024 rows (i.e., N=1024), the number (M) of first level switches is equal to 16, and the number (P) of rows coupled to each second level multiplexer is 64. In this case, 10 bits (e.g., ADDR[9:0]) can be employed to specify a particular row. For example, the four upper bits (e.g., ADDR[9:6]) may be utilized to select one of the sixteen first level switches. Decode logic (e.g., 312, 322, 332) can be utilized generate control signals for the respective first level switch (e.g., 310, 320, 330). For example, decode circuit (e.g., 312, 322, 332) can implement the following logic. When the four upper bits (ADDR[9:6]) are equal to “0000,” the first switch (switch_1) 310 is selected; when the four upper bits (ADDR[9:6]) are equal to “0001,” the second switch (switch_2) 320 is selected; . . . when the four upper bits (ADDR[9:6]) are equal to “1111,” switch_16 330 is selected.

The boost signal interface mechanism 150 also includes a plurality of second level multiplexers 308 (e.g., MUX_1 340, MUX_2 350, . . . switch_M 360). Each multiplexer (340, 350, 360) includes a first input coupled to the output of a respective first level switch to receive the boost signal, a second input for receiving a multiplexer control signal (e.g., M1_CONTROL signal, M2_CONTROL signal, . . . , MM_CONTROL signal), and a plurality of outputs that drive different rows of the pixel array.

Each switch in the second level multiplexers includes decode logic (e.g., represented by decode blocks 342, 352 and 362) that receives selected bits from the row address and based thereon generates a control signal for controlling the respective switch. For example, the control signal may be utilized to turn ON or OFF a respective switch. The decode logic 342, 352, 362 may be implemented with well-known logic circuits and logic gates. For example, decode logic can be an AND gate with inputs that receive selected bits from the row address and a single output that generates a single control signal that selectively turns ON or OFF the respective switch in the MUX (e.g., 340, 350, 360). For a first switch in the MUX denoted by binary “000000”, the decode logic can be implemented with an AND gate with inverted inputs for all received address bits. For a second switch in the MUX is denoted by “000001”, the decode logic can be implemented with an AND gate that includes inverted inputs for the upper five bits and a non-inverted input for the lowest bit.

The selected output provides the boost signal to a selected row based on the multiplexer control signal (e.g., M1_CONTROL signal, M2_CONTROL signal, . . . , MM_CONTROL signal) for that multiplexer. In one embodiment, the first level switches screen and ensure that the boost signal is routed through only one of the multiplexers at any one time. Also, each multiplexer asserts only one of its outputs at any one time. It is noted that the outputs of each MUX are coupled to a reset line corresponding to a respective row of pixels.

For example, MUX_1 340 includes P output signals that are generated by P outputs 344. Similarly, MUX_2 350 includes P output signals that are generated by P outputs 354. Also, MUX_M 360 includes P output signals that are generated by P outputs 364. As noted previously, in one embodiment, ten bits (e.g., ADDR[9:0]) are employed to specify a particular row. For example, the six lower bits (e.g., ADDR[5:0]) may be utilized to select one of the sixty-four outputs of each multiplexer. When the six lower bits (ADDR[5:0]) are equal to “000000,” the first output of a multiplexer selected by a corresponding first-level switch (e.g., MUX_1 340) is selected; when the six lower bits (ADDR[5:0]) are equal to “000001,” the second output of a multiplexer selected by a corresponding first-level switch (e.g., second output of MUX_1 340) is selected; . . . when the six lower bits (ADDR[5:0]) are equal to “111111,” output sixty-four of the multiplexer selected by a corresponding first-level switch (e.g., output sixty-four of MUX_1 340) is selected.

It is noted that the number of pixels in the pixel array, the number of rows (N), the number of columns, the value of M, and the value of P are not limited to these exemplary values provided above, but may be other values to suit a particular application. The general relationship between the number of rows (N), the number of primary switches (M), and the number (P) of rows per primary switch may be given by the following expression: N/M=P when the number of rows is a power of two.

However, it is noted that the number of rows need not be a power of two. When the number of rows is not a power of two, the number of primary switches may not be a power of two, and the number of secondary switches may not be a power of two. For example, the actual number of primary switches employed may be less than the maximum number of primary switches supported by the address bits reserved to select one of the primary switches, and the actual number of secondary switches used for a particular block of secondary switches may be less than the maximum number of secondary switches supported by the address bits reserved to control the secondary switches.

In one embodiment, the pixel array includes 1024 rows, and the boost signal interface mechanism 150 employs 16 primary switches or blocks (e.g., first level switches) and 16 second level multiplexers, where each multiplexer is coupled to 64 rows. The hierarchical structure effectively reduces the parasitic capacitance seen by the boost signal generation circuit 110 by isolating the boost signal generation circuit 110 from the capacitive load of the rows associated to the non-selected primary switches.

It is noted that in other embodiments the hierarchical structure includes more than two levels of switches. For example, consider the case where there are three levels of switches (e.g., a three-level switch matrix) to route a boost signal to a pixel array with 1024 rows. Ten address bits are employed to specify a particular row. The upper three bits specify one of eight switches in the first level; the next three bits specify one of eight switches in the second level, and the lower four bits specify one of sixteen outputs of a multiplexer that is in the third level. In this case, the capacitive load (e.g., parasitic capacitance) seen by the boost signal generation circuit is 8 units of capacitance (from switches in the first level) plus 8 units of capacitance (from switches in the second level) plus 16 (from switches in the third level) for a total of 32 units of capacitance. It is noted that the number of levels, the total number bits in an address utilized for switching, and the number of bits employed to control each level of switches may be adjusted to suit the particular requirements of an application. In this manner, the number of off switches and the corresponding capacitive load of the rows coupled to these off switches may be reduced, thereby isolating the boost signal generator circuit from un-used rows since only one row is acted upon at one time. Stated differently, the interface according to the invention minimizes the exposure of the boost signal generation circuit to capacitive loads of rows that are not utilized at the current time.

When compared to the embodiment illustrated in FIG. 2, which has a capacitive load (C_L) of 1024 units (i.e., one unit of capacitance for each row), this embodiment has a capacitive load of 64 units plus 16 units attributable to the other primary switches for a total of 80 units of parasitic capacitance. Consequently, the embodiment of FIG. 3 is preferred when a design requires a reduced parasitic capacitance, since the load capacitances of the pixels in the rows associated with the primary switches that are OFF (i.e., non-selected primary switches) are not seen by the boost signal generation circuit 110.

In another alternative embodiment of the boost signal interface mechanism according to the invention, the first level of primary switches are eliminated, and a plurality of boost generator circuits are provided for the pixel array. In this embodiment, a boost signal generation circuit is provided for every P rows, where P is equal to N/C, where N is the number of total rows in the pixel array, and C is the number of boost signal generation circuits utilized. This embodiment has a reduced parasitic capacitance when compared with the embodiment of FIG. 2 since each boost signal generation circuit is exposed to P (e.g., 64) units of capacitive load corresponding to P rows instead of N (e.g., 1024) units of capacitive load that the “flat” design of FIG. 2 presented to the boost signal generation circuit 110. However, it is noted that the components utilized in the different boost signal generation circuits must be precisely matched due to the nature of analog design.

It is noted that a mis-match of analog components used in the different boost signal generation circuits can introduce row-to-row offsets. These row-to-row offsets are not desirable because these offsets and differences between rows can cause artifacts (e.g., lines or other noise in the captured image), which are also known as coherent noise or pattern noise. The human eye is very sensitive to such noise that may appear to a user as one or more rows of pixels being either brighter or darker than adjacent blocks of rows.

As compared to this embodiment, the hierarchical switching structure employed by this embodiment of the invention shown in FIG. 3 minimizes row-to-row offsets since a single boost signal generation circuit 110 is utilized. The hierarchical switching structure can also be implemented with less area than the embodiment with multiple boost signal generators since a single boost signal generation circuit 110 is utilized.

Exemplary Circuit Implementation of Boost Signal Interface Mechanism

FIG. 4 is a circuit diagram of an exemplary implementation of the boost signal interface mechanism of FIG. 3 according to one embodiment of the invention. The first primary switch (switch_1 310) can be implemented with a circuit configuration 410 that includes transistors M1 to M6 and an inverter I_2. It is noted that in this circuit configuration 410 the gate electrode of transistor M5 receives a decoded address 420 that in one example is a result (e.g., a single bit) from one or more logical operation performed on the four upper bits of the row address (e.g., ADDR[9:6]). The circuit configuration 410 may be repeated for each primary switch (e.g., 310 to 330) in the first level 304 of switches.

The source electrode of transistors M3 and M4 is denoted “B”. It is noted that node B is coupled to each block (e.g., 416) that corresponds to the rows that are coupled to the first multiplexer (MUX_1 340). In this example, the configuration 412 that includes transistors M7 to M12 and an inverter I_3 is repeated for each row (e.g., rows 2 to P) that is coupled to the first multiplexer (MUX_1 340). Similarly, the configuration 412 may be repeated for each row (e.g., rows 1 to P) that is coupled to the second multiplexer (MUX_2 350), for each row (e.g., rows 1 to P) that is coupled to each multiplexer thereafter, and for each row (e.g., rows 1 to P) that is coupled to the last multiplexer_M (MUX_M 360).

It is noted that NAND gate 450 includes a first input for receiving the reset enable signal 156 and a second input for receiving a decoded address 424. The output of the NAND gate 450 is denoted “A” and is provided to the gate of transistor M9, for example, and to a corresponding transistor in each switch of the multiplexers in the second level of multiplexers. In one embodiment, the decoded address 424 is a result (e.g., a single bit) from one or more logical operation performed on the six lower bits of the row address (e.g., ADDR[5:0]).

It is noted that the above circuit implementation is based on signals that are active high signals. However, it is noted that one or more of the signals may be active low signals. In this case, one of ordinary skill in the art can readily re-configure the circuit to perform the desired function, where one or more of the signals are active low signals. In one embodiment, the transistors can be implemented with MOS field effect transistors (e.g., p-channel MOSFETs and n-channel MOSFETS). However, it is noted that other types of transistors and switches may be utilized to implement the interface according to the invention.

Processing Performed by the Boost Signal Interface Mechanism

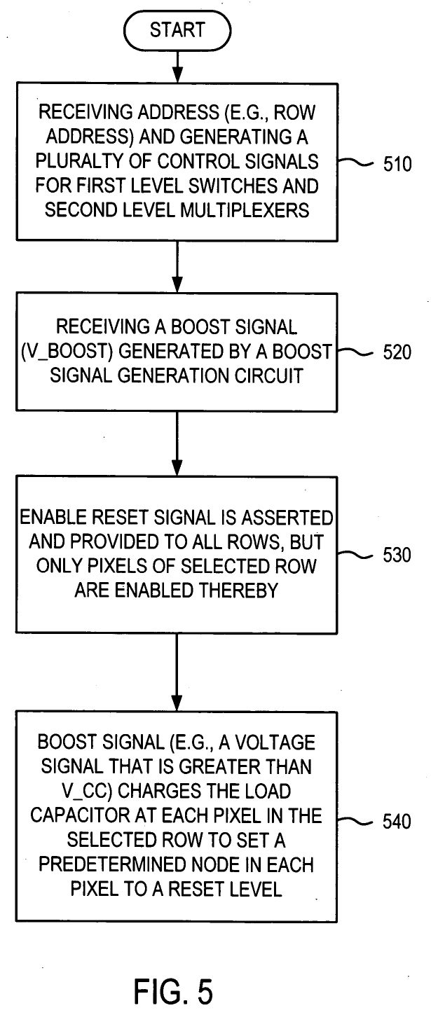

FIG. 5 is a flowchart illustrating a method performed by the boost signal interface mechanism of FIG. 3 according to one embodiment of the invention. In step 510, an address (e.g., a row address) is received and control signals for the first level switches and second level multiplexers are generated based thereon. For example, a plurality of switch control signals may be generated based on selected bits of the row address (e.g., the upper four bits ADDR[9:6]). These switch control signals are received by a respective switch (e.g., switch_1 . . . switch_M). A plurality of multiplexer control signals may be generated based on selected bits of the row address (e.g., the lower six bits ADDR[5:0]). These multiplexer control signals are utilized to select or specify a particular row coupled to the multiplexer. As described previously, a logic circuit may be utilized to generate control signals (e.g., switch control signals and MUX control signals) based on one or more bits of the row address.

In step 520, a boost signal (V_boost) is received from a boost signal generation circuit 110, for example. For example, in this step, the boost signal generation circuit 110 is activated or turned on by the timing controller circuit 170, which may also be utilized to generate the reset enable signal 156 and the control signals 158 (e.g., row address signals).

In step 530, an enable reset signal is asserted and provided to all rows, but only pixels of the selected row are enabled thereby. In step 540, a boost signal (e.g., a voltage signal that is greater than V_CC) charges the load capacitor at each pixel in the selected row, which in turn sets a predetermined node in each pixel to a predetermined reset level.

In this manner, the boost signal interface mechanism 150 provides a path or routes the boost signal from the boost signal generation circuit 110 to a particular row of the pixel array 160 based on the switch control signals and the multiplexer control signals generated or decoded from the row address, for example. These control signals specify one of the primary switches in the first level of switches and also specify one of the outputs of a selected multiplexer, which corresponds to a selected row, in the second level of multiplexers. Consequently, when the enable reset is asserted, the boost signal interface mechanism provides a path for charge to discharge from the boost capacitor and to charge the load capacitors of each pixel in the selected row.

Implementation of Boost Signal Interface Mechanism in a Camera Module

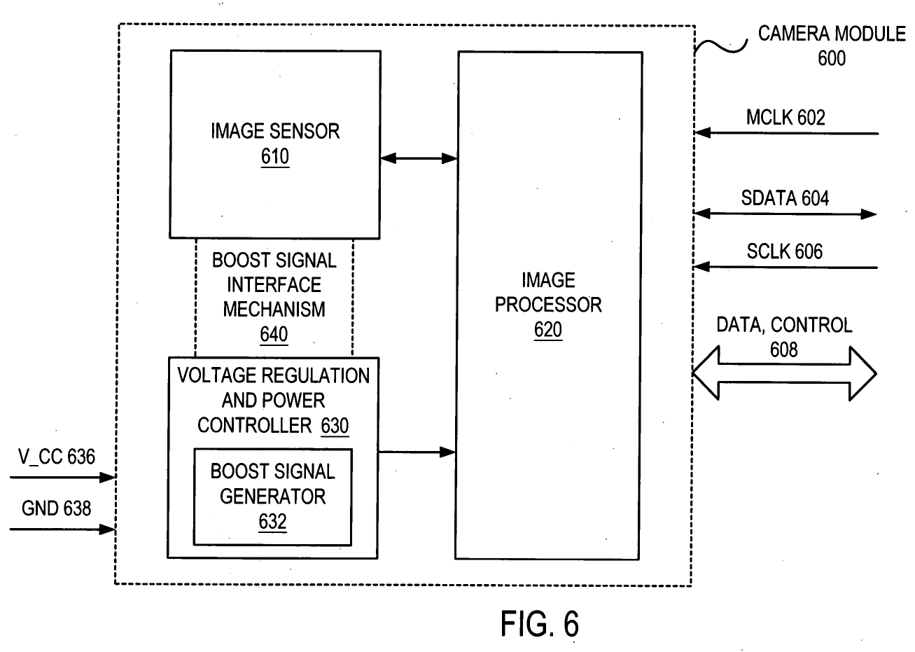

FIG. 6 is a block diagram illustrating a camera module 600 that includes the boost signal interface mechanism 640 according to one embodiment of the invention. The camera module 600 also includes an image sensor 610, an image processor 620, a power regulation circuit 630, and optics 650 (e.g., a F2.8 lens). The image sensor 610 converts light into electrical signal representing the received light (e.g., integration and readout). The image sensor 610 can also perform signal processing on the electrical signals in the analog domain. The image sensor 610 then converts the analog signals into the digital domain for storage or further processing by the image processor 620. The image processor 620 performs image compression (e.g., JPEG compression), conversion between different image formats, and other image processing as described in greater detail hereinafter.

Camera modules (e.g., Agilent ADCM-3800 1.3 Mega-pixel Resolution CMOS Camera Module) are available from the assignee of the present application. The camera module 600 includes an input for receiving a clock signal 602 (e.g., MCLK signal) and inputs for receiving power signals (e.g., GND 638 and V_CC 636). The camera module 600 also includes a parallel output (e.g., CCIR 656) for providing data and control signals 608 and a serial port that includes a SDATA signal 604 and a SCLK signal 606.

The image sensor 610 can include hardware, software, firmware or a combination thereof to perform one or more of the following operations: A/D conversion, control of the window size, adjusting pixel gain (e.g., color gain ratios), and timing control.

The image processor 620 can include hardware, software, firmware or a combination thereof to perform one or more of the following operations: automatic exposure, automatic white balance processing, automatic flicker correction, pixel correction, demosaic processing, sharpening, sizing, color balance processing, gamma correction, color space conversion (e.g., RGB or YCbCr), downsampling, and compression (e.g., JPEG).

A voltage regulation and power control functional block 630 receives a ground (GND) potential signal 638 and a power signal 636 (e.g., V_CC). The voltage regulation and power control functional block 630 provides power to the remaining functional blocks (e.g., the image sensor and the image processor). A boost signal generation circuit 632 that generates a boost signal can be incorporated in the voltage regulation and power control functional block 630. In one embodiment, the boost signal interface mechanism 640 according to the invention is coupled to the voltage regulation and power control functional block 630 and the image sensor 610 (e.g., a pixel array disposed in the image sensor 610) and provides an interface there between. Alternatively, the boost signal interface mechanism 640 may be embodied in the image sensor 610 or embodied in the voltage regulation and power controller 630.

In one example, the camera module that includes the boost signal interface mechanism is incorporated into a cellular telephone camera (“camera telephone”). The camera telephone includes a power supply (e.g., a battery), cellular telephone electronics, and a camera module. The operation and construction of cellular telephone electronics are known by those of ordinary skill in the art and will not be described further herein.

The interface mechanism according to the invention may be incorporated into a variety of different electronic devices that include, but are not limited to, mobile phones, video phones, personal digital assistants, image-enabled appliances, digital image capture cameras (e.g., still and video cameras), digital still mini cameras, embedded automotive applications, and monitoring equipment.

It is noted that the interface mechanisms according to the invention are not limited to the embodiments and applications described above, but instead can be utilized to route other types of signals to other types of arrays for other applications. For example, the interface mechanism according to the invention can be utilized to multiplex, distribute or route any signal (e.g., a signal that drives a gate of a transistor in an element of an array) to an array of elements (e.g., an array of memory elements).

In the foregoing specification, the invention has been described with reference to specific embodiments thereof. It will, however, be evident that various modifications and changes may be made thereto without departing from the broader scope of the invention. The specification and drawings are, accordingly, to be regarded in an illustrative rather than a restrictive sense.

What is claimed is:

1. An apparatus for providing a boost signal to a pixel array that includes a plurality of rows, the apparatus comprising:
a) a first input that receives a boost signal;
b) a second input that receives at least one control signal;
c) a third input that receives a reset enable signal;
d) a plurality of outputs; wherein each output is coupled to a corresponding row of the pixel array; wherein the boost signal is selectively provided at one of the outputs based on the control signal and the reset enable signal.

2. The apparatus of claim 1 wherein the apparatus includes a hierarchical switching structure that includes
a plurality of first level switches; wherein each switch includes an input that receives the boost signal, an input that receives a switch control signal and an output that provides the boost signal based on the switch control signal; and
a plurality of second level multiplexers; wherein each multiplexor includes an input coupled to the output of a respective first level switch that receives the boost signal, a second input that receives a multiplexor control signal, and a plurality of outputs; wherein one of the outputs provides the boost signal based on the multiplexer control signal.

3. The apparatus of claim 1 wherein the pixel array includes a plurality of rows that are not selected at any one time; wherein the non-selected row each includes a parasitic capacitance, the apparatus further comprising:
an effective parasitic capacitance reduction mechanism that isolates the first input from the parasitic capacitance of a plurality of non-selected rows.

4. The apparatus of claim 1 wherein the apparatus is incorporated in one of mobile camera handsets, video telephones, personal digital assistants, image-enabled appliances, digital still mini cameras, embedded automotive applications, and monitoring equipment.

5. The apparatus of claim 2 wherein the hierarchical switching structure minimizes row-to-row offsets.

6. The apparatus of claim 2 wherein the hierarchical switching structure includes a logic circuit for each first level switch that receives selected bits from a row address and based thereon generates a control signal for controlling the respective first level switch; wherein the hierarchical switching structure includes a logic circuit for each second level switch that receives selected bits from a row address and based thereon generates a control signal for controlling the respective first level switch.

7. The apparatus of claim 2 wherein the hierarchical switching structure minimizes area utilized by the boost signal interface mechanism.

8. A camera module comprising:
optics;
an image sensor that includes a pixel array that includes a plurality of rows;
an image processor;
a boost signal generator;
a boost signal interface mechanism that includes
a first input coupled to the boost signal generator that receives a boost signal;
a second input that receives at least one control signal;
a third input that receives a reset enable signal;
a plurality of outputs; wherein each output is coupled to a corresponding row of the pixel array; wherein the boost signal is selectively provided at one of the outputs based on the control signal and the reset enable signal.

9. The camera module of claim 8 wherein the boost signal interface mechanism includes a hierarchical switching structure that includes
a plurality of first level switches; wherein each switch includes an input that receives the boost signal, an input that receives a switch control signal and an output that provides the boost signal based on the switch control signal; and
a plurality of second level multiplexers; wherein each multiplexor includes an input coupled to the output of a respective first level switch that receives the boost signal, a second input that receives a multiplexor control signal, and a plurality of outputs; wherein one of the outputs provides the boost signal based on the multiplexer control signal.

10. The system of claim 8 wherein the pixel array includes a plurality of rows that are not selected at any one time; wherein the non-selected row each includes a parasitic capacitance, the boost signal interface mechanism further comprising:
an effective parasitic capacitance reduction mechanism that isolates the first input from the parasitic capacitance of a plurality of non-selected rows.

11. The system of claim 8 wherein the apparatus is incorporated in one of mobile camera handsets, video telephones, personal digital assistants, image-enabled appliances, digital still mini cameras, embedded automotive applications, monitoring equipment.

12. The system of claim 9 wherein the hierarchical switching structure minimizes row-to-row offsets.

13. The system of claim 9 wherein the hierarchical switching structure minimizes parasitic capacitance of the boost signal interface mechanism.

14. The system of claim 9 wherein the hierarchical switching structure minimizes area utilized by the boost signal interface mechanism.

15. A method for providing a boost signal to an array that includes a plurality of pixels; wherein the pixels are arranged in rows; wherein the method includes:
providing a boost signal interface mechanism that is coupled to the pixel array;
the boost signal interface mechanism receiving a boost signal;
the boost signal interface mechanism receiving at least one control signal;
the boost signal interface mechanism receiving a reset enable signal; and
boost signal interface mechanism selectively providing the boost signal to one of the rows of the pixel array based on the control signal and the reset enable signal.

16. The method of claim 15 wherein providing a boost signal interface mechanism that is coupled to the pixel array includes;
providing a boost signal interface mechanism that includes a hierarchical switching structure; wherein the hierarchical switching structure includes a first set of switches and a second set of multiplexers; wherein each multiplexer is coupled to a corresponding switch.

17. The method of claim 16 wherein the boost signal interface mechanism receiving at least one control signal includes
receiving at least one switch control signal for each switch; and
receiving at least one multiplexer control signal for each multiplexer.

18. The method of claim 16 wherein the hierarchical switching structure minimizes row-to-row offsets.

19. The method of claim 16 wherein the hierarchical switching structure minimizes parasitic capacitance of the boost signal interface mechanism.

20. The method of claim 16 wherein the hierarchical switching structure conserves area by utilized by the boost signal interface mechanism.
